(19) United States
(12) Patent Application Publication
(10) Pub. No.: US 2004/0045503 A1
(43) Pub. Date: Mar. 11, 2004

(54) Method for treating a surface of a reaction chamber

(76) Inventors: Jong-Myeong Lee, Gyeonggi-do (KR); In-Sun Park, Gyeonggi-do (KR); Hyeon-Deok Lee, Seoul (KR); Jong-Sik Chun, Gyeonggi-do (KR)

Correspondence Address: MYERS BIGEL SIBLEY & SAJOVEC, PO BOX 37428, RALEIGH, NC, 27627, US

(21) Appl. No.: 10/420,503

(22) Filed: Apr. 22, 2003

(30) Foreign Application Priority Data
Sep. 6, 2002 (KR) 2002-0053883

(51) Int. Cl. C23C 16/00; B05D 7/22

(52) U.S. Cl. 118/712; 427/255.28; 427/230; 427/569

(57) ABSTRACT

A method for treating a surface of a reaction chamber is provided. The reaction chamber is adapted for use in forming a first metal film on a substrate and has a second metal film on the surface of the reaction chamber. The second metal film is formed by a chemical vapor deposition process for forming the first metal film using a metal organic precursor having a selective deposition characteristic relative to a conductive material. The method includes converting the second metal film on the surface of the reaction chamber into an insulation film. The step of converting the second metal film into an insulation film may include oxidizing or nitrifying the second metal film.

### RELATED APPLICATION

The present application claims priority from Korean Patent Application No. 2002-53883, filed Sep. 6, 2002, the disclosure of which is incorporated herein by reference in its entirety.

### FIELD OF THE INVENTION

The present invention relates to methods for treating a surface of a reaction chamber, and more particularly, to a method for treating a surface of a reaction chamber for forming a metal film on a semiconductor substrate utilizing a metal organic chemical vapor deposition process.

### DESCRIPTION OF THE RELATED ART

Generally, semiconductor devices are manufactured through unit processes including a deposition process, a photolithography process, an etching process, a chemical-mechanical polishing process, a cleaning process, a drying process and so on. In those unit processes, the deposition process is executed to form a film on a semiconductor substrate. The deposition process has become important in semiconductor manufacturing technology as the patterns formed on the semiconductor substrate have become minute and the aspect ratios of the patterns have increased.

A semiconductor device generally includes many elements such as transistors, resistors, and capacitors. Also, metal wirings are typically required for connecting the elements of the semiconductor device formed on the semiconductor substrate. The metal wirings transmit electrical signals and therefore should have low electrical resistance and high reliability.

Recently, the width and the thickness of such metal wirings have greatly decreased and the size of contact holes has also decreased as the integration density of semiconductor devices has increased. Thus, the process for burying the contact hole has become more important. In general, a physical vapor deposition process is utilized for burying the contact hole during the process for forming the metal wiring. However, when the contact hole has a high aspect ratio, the contact formed in the contact hole typically does not have acceptable step coverage during the physical vapor deposition process due to a geometric shadow effect.

To solve the above-mentioned problem, the metal wiring may be formed through a selective metal organic chemical vapor deposition (MOCVD) process using a metal organic precursor. In the selective MOCVD process, an aluminum precursor is mainly used for forming an aluminum film on the semiconductor substrate such that the aluminum film has acceptable step coverage.

The selective MOCVD process is performed to form a metal film on the semiconductor substrate using a metal organic precursor having a selective deposition characteristic relative to a conductive material. For example, after the insulation film formed on the semiconductor substrate is patterned to expose the predetermined portion of the underlying wiring formed between the semiconductor substrate and the insulation film, the metal wiring is formed at the predetermined portion of the underlying wiring using the metal organic precursor having the selective deposition characteristic.

When the selective MOCVD process is executed with the aluminum precursor, an aluminum film is deposited not only on the semiconductor substrate but also on the inside surface of a reaction chamber. That is, a first aluminum film is formed on the semiconductor substrate, while a second aluminum film is formed on the inner surface of the reaction chamber, on a pedestal for supporting the semiconductor substrate, and on a gas spray head for supplying reaction gas. The second aluminum film formed on the inside surface of the reaction chamber may cause impurities during the selective MOCVD process. Particularly, the temperature of the semiconductor substrate may be irregular because of the second aluminum film formed on the pedestal. Thus, the second aluminum film formed on the inside surface of the reaction chamber should be removed using a pertinent treatment.

To remove the aluminum film formed on the inside surface of the reaction chamber, there may be provided an in situ cleaning process using a reaction gas such as Cl₂, ClF₃ or NF₃. Also, a shield can be installed on the inside surface of the reaction chamber. The shield may be periodically changed in order to prevent the aluminum film from forming on the inside surface of the reaction chamber.

Regarding the in situ cleaning process using the reaction gas, great care may be required in handling the reaction gas because the reaction gas is poisonous and very reactive. In addition, the processing time may be increased because the reaction gas can be completely exhausted from the reaction chamber after the cleaning of the reaction chamber. Meanwhile, the shield may not completely protect the inside surface of the reaction chamber, and changing the shield may require a substantial amount of time.

### SUMMARY OF THE INVENTION

According to method embodiments of the present invention, a method for treating a surface of a reaction chamber, the reaction chamber being adapted for use in forming a first metal film on a substrate and having a second metal film on the surface of the reaction chamber, the second metal film being formed by a chemical vapor deposition process for forming the first metal film using a metal organic precursor having a selective deposition characteristic relative to a conductive material, includes converting the second metal film on the surface of the reaction chamber into an insulation film. The step of converting the second metal film into the insulation film may include oxidizing or nitrifying the second metal film.

According to further method embodiments of the present invention, a method for treating a surface of a reaction chamber includes: loading a substrate having a conductive material film into a reaction chamber; forming a first metal film on the substrate by providing a metal organic precursor in the reaction chamber; unloading the substrate having the first metal film from the reaction chamber; repeatedly performing the foregoing steps for a prescribed period of time such that a second metal film is formed on the surface of the reaction chamber; and converting the second metal film formed on the surface of the reaction chamber into an insulation film with a reaction material including oxygen and/or nitrogen.

According to further method embodiments of the present invention, a method for treating a surface of a reaction chamber, the reaction chamber being adapted for use in forming a first metal film on a substrate, includes: forming a second metal film on the surface of the reaction chamber with a metal organic precursor in the reaction chamber, the metal organic precursor having a selective deposition characteristic relative to a conductive material; and converting the second metal film into an insulation film with a reaction material including oxygen and/or nitrogen in the reaction chamber.

According to further method embodiments of the present invention, a method for treating a surface of a reaction chamber includes: conducting a chemical vapor deposition process in the reaction chamber using a metal organic precursor having a selective deposition characteristic relative to a conductive material to form a metal film on the surface of the reaction chamber; and converting the metal film on the surface of the reaction chamber into an insulation film. The step of converting the metal film into the insulation film may include oxidizing and/or nitrifying the metal film.

According to further embodiments of the present invention, an apparatus for forming a first metal film on a substrate includes a reaction chamber having an interior surface. An insulation film is disposed on the interior surface. The insulation film is formed of an oxidized and/or nitrified second metal film formed by a selective metal organic chemical vapor deposition process.

### BRIEF DESCRIPTION OF THE DRAWINGS

FIG. 1 is a flow chart illustrating method embodiments for treating the surface of a reaction chamber according to embodiments of the present invention;

FIG. 2 is a cross-sectional view illustrating a reaction chamber for forming an aluminum film according to embodiments of the present invention;

FIG. 3 is a diagram representing the structural formula of dimethyl aluminum hydride (DMAH);

FIG. 4 is a diagram representing the structural formula of dimethylethyl amine alane (DMEAA); and

FIG. 5 is a diagram representing the structural formula of methyl pyrrolidine alane (MPA).

### DETAILED DESCRIPTION OF EMBODIMENTS OF THE PRESENT INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions may be exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present. Moreover, each embodiment described and illustrated herein includes its complementary conductivity type embodiment as well.

Embodiments of the present invention provide methods for treating the surface (e.g., an interior surface) of a reaction chamber of the type used for performing a selective metal organic chemical vapor deposition (MOCVD) process to form a first metal film on a substrate in the reaction chamber. The methods for treating the surface of the reaction chamber may serve to restrain or inhibit the deposition of metal on the surface of the reaction chamber, for example, as a result of metal organic precursor provided in the reaction chamber during one or more subsequent MOCVD processes for forming the first metal film on the substrate or a further substrate or substrates.

According to some method embodiments, a method as follows is provided for treating the surface of a reaction chamber for performing a selective metal organic chemical vapor deposition process. A first metal (e.g., aluminum) film is formed on a substrate loaded in the reaction chamber by supplying a metal (e.g., aluminum) precursor having a selective deposition characteristic relative to a conductive material. A second metal (e.g., aluminum) film is formed on an inside surface of the reaction chamber during the formation of the first metal film. The second metal film is changed or converted into an insulation film, such as an aluminum oxide film or an aluminum nitride film, using a reaction material including oxygen or nitrogen. The insulation film can inhibit the further formation of the second metal film on the inside surface of the reaction chamber. According to some embodiments, the metal organic precursor is preferably an aluminum precursor, the first metal film is preferably a first aluminum film, and the second metal film is preferably a second aluminum film.

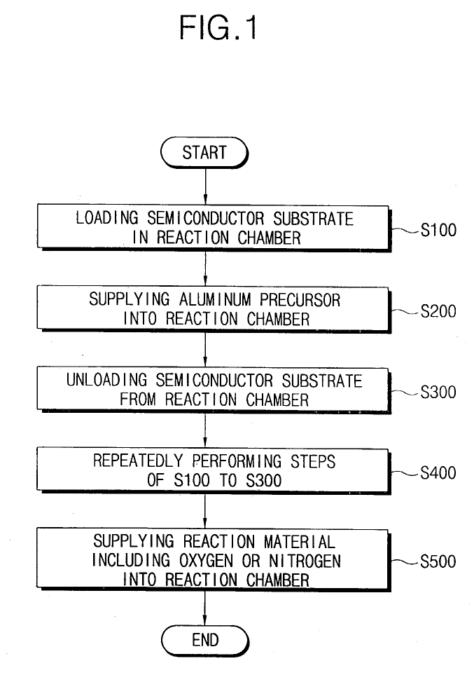

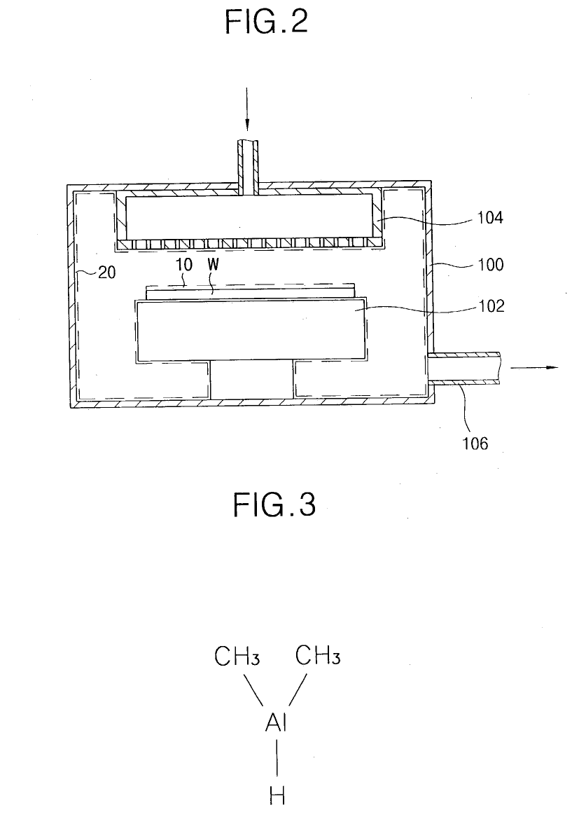

FIG. 1 is a flow chart illustrating method embodiments for treating the surface of a reaction chamber 100 according to embodiments of the present invention. FIG. 2 is a cross-sectional view illustrating the reaction chamber 100 for forming an aluminum film according to embodiments of the present invention.

Referring to FIGS. 1 and 2, the reaction chamber 100 includes a pedestal 102 for supporting a semiconductor substrate W, a gas spray head 104 for providing an aluminum precursor into the reaction chamber 100 to form a first aluminum film 10 on the semiconductor substrate W, and an exhaust port 106.

A conduction film including a conductive material is formed on the semiconductor substrate W. A metal deposition block layer is formed on the conduction film to limit deposition of metal for forming a metal wiring to a specific region or regions of the conduction film. The metal deposition block layer may include a metal oxide film or a metal nitride film. For example, after the conduction film is formed on the semiconductor substrate W, the metal deposition block layer may be formed on substantially the entire conduction film except the specific portion of the conduction film by oxidizing the conduction film other than the specific portion.

The conduction film may include, for example, aluminum (Al), polysilicon, ruthenium (Ru), platinum (Pt), iridium (kr), yttrium (Y), zirconium (Zr), chrome (Cr), cobalt (Co), nickel (Ni), titanium (Ti), titanium nitride (TiN), tantalum (Ta), tantalum nitride (TaN), tungsten (W), and/or tungsten nitride (WN). In addition, the conduction film can include mixtures having at least two of those metals and metal nitrides. The conduction film may serve as a metal barrier film during the formation of a transistor or a capacitor of a semiconductor device, and the first aluminum film 10 may serve as the metal wiring on the semiconductor substrate W.

The metal deposition block layer may include aluminum nitrides or metal oxides including copper (Cu), silver (Ag), gold (Au), tungsten (W), molybdenum (Mo), tantalum (Ta), zirconium (Zr), strontium (Sr), magnesium (Mg), barium (Ba), calcium (Ca), cerium (Ce), yttrium (Y), chrome (Cr), cobalt (Co), nickel (Ni), and/or titanium (Ti).

Hereinafter, the process for forming the first aluminum film 10 and an insulation film on the semiconductor substrate W and on the inside surface of the reaction chamber 100 will be described in detail with reference to FIG. 1.

First, the semiconductor substrate W having the conduction film formed thereon is loaded onto the pedestal 102 in the reaction chamber 100 (step S100).

Then, an aluminum precursor in gas phase is supplied into the reaction chamber 100 through the gas spray head 104 or other suitable supply inlet in order to form the first aluminum film 10 on the semiconductor substrate W (step S200). The aluminum precursor may be transferred using a carrier gas.

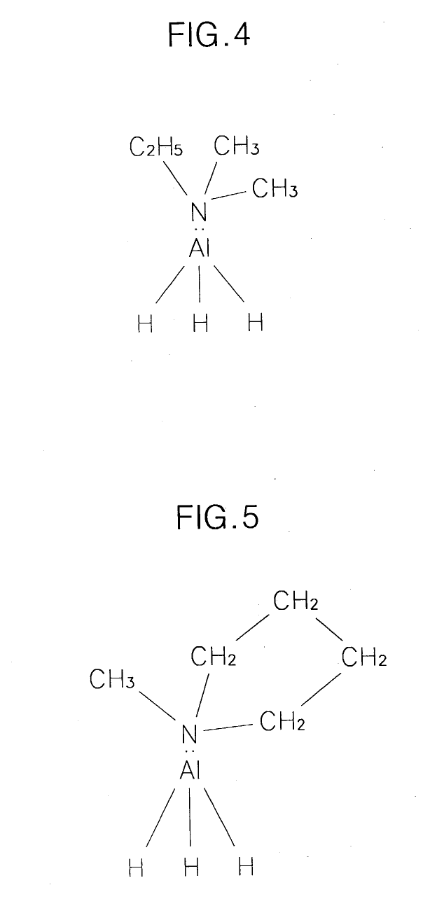

The aluminum precursor can include dimethyl aluminum hydride (DMAH) or dimethylethyl amine alane (DMEAA). The aluminum precursor can include methyl pyrrolidine alane (MPA). FIG. 3 shows the structural formula of dimethyl aluminum hydride (DMAH). FIG. 4 shows the structural formula of dimethylethyl amine alane (DMEAA). FIG. 5 shows the structural formula of methyl pyrrolidine alane (MPA).

Examples of the organic metal precursor of the present invention include trimethyl aluminum ((CH₃)₃Al), triethyl aluminum ((C₂H₅)₃Al), triisobutyl aluminum (((CH₃)₂CHCH₂)₃Al), dimethyl aluminum hydride ((CH₃)₂AlH), dimethylethyl amine alane ((CH₃)₂C₂H₅N:AlH₃), and alkyl pyrrolidine alane (R(C₄H₈)N:AlH₃, wherein R indicates hydrogen or alkyl of CₙH₂ₙ₊₁), and tritertiarybutyl aluminum (((CH₃)₃C)₃Al).

When the R group included in the alkyl pyrrolidine alane (R(C₄H₈)N:AlH₃) is methyl (CH₃), the alkyl pyrrolidine alane corresponds to methyl pyrrolidine alane (MPA). The alkyl pyrrolidine alane is a very stable precursor in comparison with the dimethylethyl amine alane (DMEAA).

In the above-mentioned aluminum precursors, the dimethyl aluminum hydride (DMAH) or the dimethylethyl amine alane (DMEAA) is preferably used. More preferably, the methyl pyrrolidine alane (MPA) is used.

The selective MOCVD process using the aluminum precursor is preferably performed at a temperature in a range corresponding to the surface reaction limited region of the aluminum. For example, the selective MOCVD process is preferably performed at a temperature less than approximately 300° C.

The aluminum precursor may be provided into the reaction chamber in a gas phase by a bubbler, a gas phase mass flow controller (MFC), or a liquid delivery system. A carrier gas for transferring the aluminum precursor may include a hydrogen (H₂) gas or an inert gas such as an argon (Ar) gas, a nitrogen (N₂) gas, a helium (He) gas. When the carrier gas includes an inert gas, a hydrogen gas may be employed as a reduction gas to accelerate the reduction reaction of the aluminum precursor.

The carrier gas can include an inert gas like argon (Ar) gas, or a hydrogen (H₂) gas. When the carrier gas includes argon gas, additional hydrogen gas can be supplied into the reaction chamber 100 as a reduction gas for accelerating the reduction reaction of the aluminum precursor. When MPA is provided into the reaction chamber 100, the temperature of the reaction chamber 100 is preferably between about 120 and 150° C., and the pressure of the reaction chamber 100 is preferably less than about 10 torr.

Once the first aluminum film 10 having desired thickness is formed on the semiconductor substrate W, the supply of MPA or other metal organic precursor is discontinued. Argon gas is provided into the reaction chamber 100 in order to purge the reaction chamber 100 through the exhaust port 106.

Subsequently, the semiconductor substrate W is unloaded from the reaction chamber 100 (step S300).

The above-described steps of S100 to S300 for depositing the first aluminum film 10 may be performed for a plurality of semiconductor substrates W (step S400). As the first aluminum films 10 are repeatedly deposited on the semiconductor substrates W, a second aluminum film 20 is formed on the inside surface of the reaction chamber 100.

The reaction chamber 100 may be formed of aluminum or stainless steel, for example. Also, elements such as the pedestal 102 and the gas spray head 104 may be formed of aluminum, stainless steel, or graphite, for example. The inside surface of the reaction chamber 100 for performing the selective metal organic chemical vapor deposition (MOCVD) process may be coated with a basic insulation film, or a shield including insulation material may be disposed inside of the reaction chamber 100. Various reaction chambers coated with basic insulation films or having shields have been disclosed. For example, Japanese Laid Open Patent Publication No. 12-124,137 discloses a plasma processing apparatus having a reaction chamber coated with aluminum oxide. Japanese Laid Open Patent Publication 8-71,408 provides a plasma-processing chamber protected by a ceramic surface selected from the group consisting of aluminum nitride, crystalline aluminum oxide, magnesium fluoride, sintered aluminum oxide and magnesium oxide.

Though the MPA can be selectively deposited relative to the conductive material, a small quantity of aluminum may be deposited on the inside surface of the reaction chamber 100 during the selective MOCVD process. As the first aluminum films 10 are formed on several semiconductor substrates W, the deposition rate of the second aluminum film 20 gradually increases with the lapse of time, because the second aluminum film 20 is conductive. The thickness of the second aluminum film 20 coated on the inside surface of the reaction chamber 20 is thereby increased.

After the first aluminum films 10 are formed on the semiconductor substrates W, the reaction gas including an oxygen gas or a nitrogen gas is supplied (e.g., through the spray head 104) into the reaction chamber 100 such that the second aluminum film 20 formed on the inside of the reaction chamber 100 is changed into an insulation film (step S500). The period for forming the insulation film on the inside surface of the reaction chamber 100 can be varied in accordance with the thickness of the first aluminum film 10 formed on the semiconductor substrate W, the sorts of the source gases, reaction temperature, and reaction time, and the like. For example, the second aluminum film 20 can be changed into the insulation film on the inside surface of the reaction chamber 100 after the first aluminum films 10 are formed on twenty-five semiconductor substrates W. Otherwise, the inner surface of the reaction chamber 100 can be treated by a quantity of the semiconductor substrates W received in a cassette or a front open unified pod (FOUP).

Examples of the reaction gas include oxygen (02), ozone (03), nitrogen (N₂), and ammonia (NH₃). The reaction gas can be supplied into the reaction chamber 100 in a plasma phase. When a nitrogen gas or an ammonia gas is provided into the reaction chamber 100 as the reaction gas, the reaction chamber 100 preferably is heated to have a temperature of more than approximately 500° C. Thus, the nitrogen gas or the ammonia gas is preferably provided into the reaction chamber 100 in a plasma phase. In addition, an oxygen gas is preferably provided into the reaction chamber 100 in a plasma phase. An oxygen plasma, a nitrogen plasma, or an ammonia plasma can be formed outside of the reaction chamber 100 using a remote plasma process. Also, the oxygen plasma, the nitrogen plasma, or the ammonia plasma can be formed directly in the reaction chamber 100.

Though the insulation film is formed on the inside surface of the reaction chamber, a small quantity of aluminum may still be deposited on the insulation film during the subsequent aluminum deposition process. The deposition rate of the aluminum on the insulation film may thereafter gradually increase due to the selectivity characteristic of the aluminum precursor. Hence, the inside surface of the reaction chamber is preferably oxidized or nitrified periodically. The periodic surface treatment of the reaction chamber 100 can extend the cleaning period of the reaction chamber 100 so that the operation rate of the aluminum deposition apparatus can be improved. Additionally, the quantity of impurities may be reduced during the formation of the first aluminum film 10.

Also, the surface treatment of the reaction chamber 100 can be performed before using the reaction chamber 100. That is, the second aluminum film 20 may be deliberately formed on the inside of the reaction chamber 100, and then changed into the insulation film so that an additional second aluminum film 20 cannot be formed on the inside surface of the reaction chamber 100 during the subsequent deposition of the first aluminum film 10. In this case, the second aluminum film 20 is not formed on the inside surface of the reaction chamber 100 after the cleaning process of the reaction chamber 100 or the initial setting of the aluminum deposition apparatus. The aluminum oxide film or the aluminum nitride film is deliberately formed on the inside surface of the reaction chamber 100 so that the additional aluminum film cannot be coated on the inside of the reaction chamber 100 during the subsequent formation of the first aluminum films 10 on the semiconductor substrates W. At this time, the aluminum oxide film or the aluminum nitride film can be coated on the inside surface of the reaction chamber 100 by supplying the reaction material into the reaction chamber.

The above-described oxidation or nitrification treatment of the second aluminum film formed on the inside surface of the reaction chamber during the formation of the first aluminum films on the semiconductor substrates changes the second aluminum film into an insulation film, namely, into an aluminum oxide Al₂O₃ film or an aluminum nitride AlN film. Therefore, the second aluminum film cannot be additionally coated on the inside surface of the reaction chamber during the process for forming the first aluminum film.

Also, the allowed period for cleaning the reaction chamber can be prolonged, and the operation rate of the aluminum deposition apparatus can be improved because the additional deposition of the second aluminum film can be restrained. Thus, time loss due to cleaning processes for the reaction chamber can be reduced.

Furthermore, the reliability of the semiconductor device can be enhanced because the quantity of impurities generated in the reaction chamber can be reduced.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A method for treating a surface of a reaction chamber, the reaction chamber being adapted for use in forming a first metal film on a substrate and having a second metal film on the surface of the reaction chamber, the second metal film being formed by a chemical vapor deposition process for forming the first metal film using a metal organic precursor having a selective deposition characteristic relative to a conductive material, the method comprising:
converting the second metal film on the surface of the reaction chamber into an insulation film.

2. The method of claim 1, wherein the step of converting the second metal film into an insulation film includes oxidizing the second metal film.

3. The method of claim 1, wherein the step of converting the second metal film into an insulation film includes nitrifying the second metal film.

4. The method of claim 1, wherein the metal organic precursor is supplied to the reaction chamber in a gas phase using a carrier gas.

5. The method of claim 1, wherein the metal organic precursor includes trimethyl aluminum ((CH₃)₃Al), triethyl aluminum ((C₂H₅)₃Al), triisobutyl aluminum (((CH₃)₂CHCH₂)₃Al), dimethyl aluminum hydride ((CH₃)₂AlH), dimethylethyl amine alane ((CH₃)₂C₂H₅N:AlH₃), alkyl pyrrolidine alane (R(C₄H₃)N:AlH₃, wherein R indicates hydrogen or alkyl of CₙH₂ₙ₊₁), and/or tritertiarybutyl aluminum (((CH₃)₃C)₃Al).

6. The method of claim 1, wherein the insulation film includes an aluminum oxide (Al₂O₃) film and/or an aluminum nitride (AlN) film.

7. The method of claim 1, wherein the insulation film is formed using any one selected from the group consisting of an oxygen (O₂) gas, an ozone (O₃) gas, a nitrogen (N₂) gas, and an ammonia (NH₃) gas.

8. The method of claim 1, wherein the insulation film is formed using a plasma selected from the group consisting of an oxygen plasma, a nitrogen plasma, and an ammonia plasma.

9. A method for treating a surface of a reaction chamber, the method comprising the steps of:
a) loading a substrate having a conductive material film into a reaction chamber;
b) forming a first metal film on the substrate by providing a metal organic precursor in the reaction chamber;
c) unloading the substrate having the first metal film from the reaction chamber;
d) repeatedly performing steps a) to c) for a prescribed period of time such that a second metal film is formed on the surface of the reaction chamber; and
e) converting the second metal film formed on the surface of the reaction chamber into an insulation film with a reaction material including oxygen and/or nitrogen.

10. The method of claim 9, wherein the metal organic precursor is an aluminum precursor, the first metal film is a first aluminum film and the second metal film is a second aluminum film.

11. The method of claim 10, wherein the aluminum precursor includes dimethyl aluminum hydride (DMAH), dimethylethyl amine alane (DMEAA), and/or methyl pyrrolidine alane (MPA).

12. The method of claim 10, wherein the aluminum precursor is supplied to the reaction chamber in a gas phase using a carrier gas.

13. The method of claim 12, wherein the carrier gas includes an inert gas and/or a hydrogen (H₂) gas.

14. The method of claim 9, wherein the reaction material includes oxygen (O₂), ozone (O₃), nitrogen (N₂) and/or ammonia (NH₃).

15. The method of claim 9, wherein the reaction material includes an oxygen plasma, a nitrogen plasma and/or an ammonia plasma.

16. The method of claim 9, wherein the insulation film includes an aluminum oxide film and/or an aluminum nitride film.

17. The method of claim 9, wherein the conductive material film includes at least one material selected from the group consisting of aluminum (Al), polysilicon, ruthenium (Ru), platinum (Pt), iridium (Ir), yttrium (Y), zirconium (Zr), chrome (Cr), cobalt (Co), nickel (Ni), titanium (Ti), titanium nitride (TiN), tantalum (Ta), tantalum nitride (TaN), tungsten (W), and tungsten nitride (WN).

18. A method for treating a surface of a reaction chamber, the reaction chamber being adapted for use in forming a first metal film on a substrate, the method comprising the steps of:
a) forming a second metal film on the surface of the reaction chamber with a metal organic precursor in the reaction chamber, the metal organic precursor having a selective deposition characteristic relative to a conductive material; and
b) converting the second metal film into an insulation film with a reaction material including oxygen and/or nitrogen in the reaction chamber.

19. The method of claim 18, wherein the metal organic precursor includes dimethyl aluminum hydride (DMAH), dimethylethyl amine alane (DMEAA), and/or methyl pyrrolidine alane (MPA).

20. The method of claim 18, wherein the metal organic precursor is transferred into the reaction chamber in a gas phase using an inert gas and/or a hydrogen gas.

21. The method of claim 18, further comprising the step of supplying a hydrogen gas for a reduction of the metal organic precursor into the reaction chamber during the step of forming the second metal film.

22. The method of claim 18, wherein the reaction material includes oxygen, ozone, nitrogen and/or ammonia.

23. The method of claim 18, wherein the reaction material includes an oxygen plasma, a nitrogen plasma, and/or an ammonia plasma.

24. The method of claim 18, wherein the insulation film includes metal nitride and/or metal oxide.

25. A method for treating a surface of a reaction chamber, the method comprising:
a) conducting a chemical vapor deposition process in the reaction chamber using a metal organic precursor having a selective deposition characteristic relative to a conductive material to form a metal film on the surface of the reaction chamber; and
b) converting the metal film on the surface of the reaction chamber into an insulation film.

26. The method of claim 25, wherein the step of converting the metal film into an insulation film includes oxidizing the metal film.

27. The method of claim 25, wherein the step of converting the metal film into an insulation film includes nitrifying the metal film.

28. An apparatus for forming a first metal film on a substrate, the apparatus comprising:
a) a reaction chamber having an interior surface; and
b) an insulation film on the interior surface, the insulation film being formed of an oxidized and/or nitrified second metal film formed by a selective metal organic chemical vapor deposition process.
